(19) United States
(12) Patent Application Publication
(10) Pub. No.: US 2024/0381590 A1
(43) Pub. Date: Nov. 14, 2024

(54) HEAT DISSIPATION STRUCTURE

(71) Applicant: Yazaki Corporation, Tokyo (JP)

(72) Inventors: Mitsuaki Morimoto, Susono-shi (JP); Chiaki Chida, Susono-shi (JP)

(73) Assignee: Yazaki Corporation, Tokyo (JP)

(21) Appl. No.: 18/629,104

(22) Filed: Apr. 8, 2024

(30) Foreign Application Priority Data
May 12, 2023 (JP) 2023-079522

(51) Int. Cl. H05K 7/20

(52) U.S. Cl. CPC H05K 7/209

(57) ABSTRACT

A heat dissipation structure, comprising includes a plate-shaped heat generation body; cooling members disposed at one side and the other side in a thickness direction of the heat generation body respectively and configured to hold the heat generation body in the thickness direction; a regulation portion provided between the cooling members holding the heat generation body and configured to regulate a distance from one of the cooling members to the other one of cooling members in the thickness direction; and a pipe connected to the cooling members. A refrigerant passage penetrating in a width direction that is orthogonal to the thickness direction is provided in the cooling members, and the pipe is provided to be able to communicate with the refrigerant passage, and the pipe is attachable to and detachable from, in the width direction, the cooling members in a state of holding the heat generation body.

### TECHNICAL FIELD

The present invention relates to a heat dissipation structure.

### BACKGROUND ART

Electric vehicles including hybrid vehicles are equipped with devices such as a battery as a power source, an inverter for controlling a motor, and a DC/DC converter. These devices often have a heat dissipation structure since the temperature thereof tends to raise during use and therefore their functionality deteriorates when the temperature rises (for example, see Patent Document 1 and Patent Document 2). A power supply device described in Patent Document 1 includes a plurality of prismatic batteries formed in a plate shape and arranged in a stacked state, and a thick plate-shaped insulating cooling spacer that is held between opposing surfaces of the adjacent prismatic batteries to be in contact therewith. Inside the insulating cooling spacer, a cooling passage is formed that penetrates in the width direction that intersects the stack direction of the prismatic batteries, and pipes that connect to an external circulation pump is connected to both end portions of this cooling passage in the width direction. The cooling liquid flows in and out through the pipes.

A stacked cooler described in Patent Document 2 includes a plurality of electronic components formed in a flat rectangular parallelepiped shape and stacked in a thickness direction, and a plurality of cooling pipes that are disposed to hold each electronic component from the thickness direction. The cooling pipe is configured of a flat portion in contact with the electronic component and a portion continuing outwardly in the width direction of the flat portion, and a cylindrical protruding pipe portion protruding toward one side and the other side in a stack direction in which the plurality of electronic components are stacked is formed in each portion continuing outwardly in the width direction of the flat portion. The protruding pipe portion of one cooling pipe is connected to the protruding pipe portion of another cooling pipe, thereby forming a flow passage for supplying or discharging the refrigerant.

### CITATION LIST

### Patent Documents

[Patent Document 1] JP 2009-9853A

[Patent Document 2] JP 2006-5014A

### SUMMARY OF THE INVENTION

### Technical Problem

However, in the power supply device described in Patent Document 1, the prismatic batteries and the insulating cooling spacers are stacked alternately such that a position of the cooling passage is likely to be misaligned due to the dimensional errors in the stack direction of the prismatic batteries and the insulating cooling spacers, the variations of the pressure generated in the stack direction, and the like. According to this configuration, as the number of stacked prismatic batteries increases, the above-mentioned errors and variations increase, and it is difficult to connect the pipes connected to the circulation pump while making it difficult to assemble the power supply device. On the other hand, in the stacked cooler described in Patent Document 2, the protruding pipe portion of one cooling pipe holding the electronic component is inserted into the protruding pipe portion of another cooling pipe in the stack direction of the electronic components, and connected thereto to configure the refrigerant flow path. In such a configuration, it is necessary to perform the assembly while performing the brazing in the state in which one protruding pipe portion is inserted into the other protruding pipe portion and then maintaining the watertightness such that it is difficult to assemble the stacked cooler. Also, when assembling the stacked cooler, it is necessary to apply a pressing force in the stack direction to hold the electronic components while they are disposed between the cooling pipes. This holding pressure may unintentionally lead to an excessive pressing force and repulsive force to the electronic components as the cooling target. Also, depending on the insertion amount of the protruding pipe portion, the pressing force and the repulsive force may fluctuate. Therefore, problems, such as the heat dissipation performance of the heat dissipation structure is degraded and the protruding pipe portion is also applied with the above-described pressure and repulsive force such that it becomes not easy to maintain the watertightness and assemble the stacked cooler.

An object of the present invention is to obtain a heat dissipation structure that suppresses an unintentional pressure from being applied to a heat dissipation target, improves the heat dissipation performance, and facilitates the assembly.

### Solution to Problem

In order to solve the above-described problem, a heat dissipation structure is provided to include a plate-shaped heat generation body; cooling members disposed at one side and the other side in a thickness direction of the heat generation body respectively and configured to hold the heat generation body in the thickness direction; a regulation portion provided between the cooling members holding the heat generation body and configured to regulate a distance from one of the cooling members to the other one of cooling members in the thickness direction; and a pipe connected to the cooling members, and the heat dissipation structure is characterized in that a refrigerant passage penetrating in a width direction that is orthogonal to the thickness direction is provided in the cooling members, and the pipe is provided to be able to communicate with the refrigerant passage, and is attachable to and detachable from, in the width direction, the cooling members in a state of holding the heat generation body.

### Effect of the Invention

According to the present invention, it is possible to obtain a heat dissipation structure that suppresses an unintentional pressure from being applied to a heat dissipation target, improves the heat dissipation performance, and facilitates the assembly.

### BRIEF DESCRIPTION OF THE DRAWINGS

FIG. 1 is an exploded perspective view showing a power supply device including a heat dissipation structure according to an embodiment of the present invention.

FIG. 2 is a perspective view showing the power supply device when an assembly thereof has been completed.

FIG. 3A is a left-side view showing a cooling plate configuring the heat dissipation structure.

FIG. 3B is a rear view showing the cooling plate.

FIG. 3C is a right-side view showing the cooling plate.

FIG. 4A is a view showing a holding space generated between the cooling plates.

FIG. 4B is a view showing part of the power supply device during the assembly.

FIG. 4C is a view showing part of the power supply device during the assembly.

FIG. 5 is an exploded perspective view showing a part of a power supply device according to a first modification example.

FIG. 6 is an exploded perspective view showing a part of a power supply device according to a second modification example.

### DESCRIPTION OF EMBODIMENTS

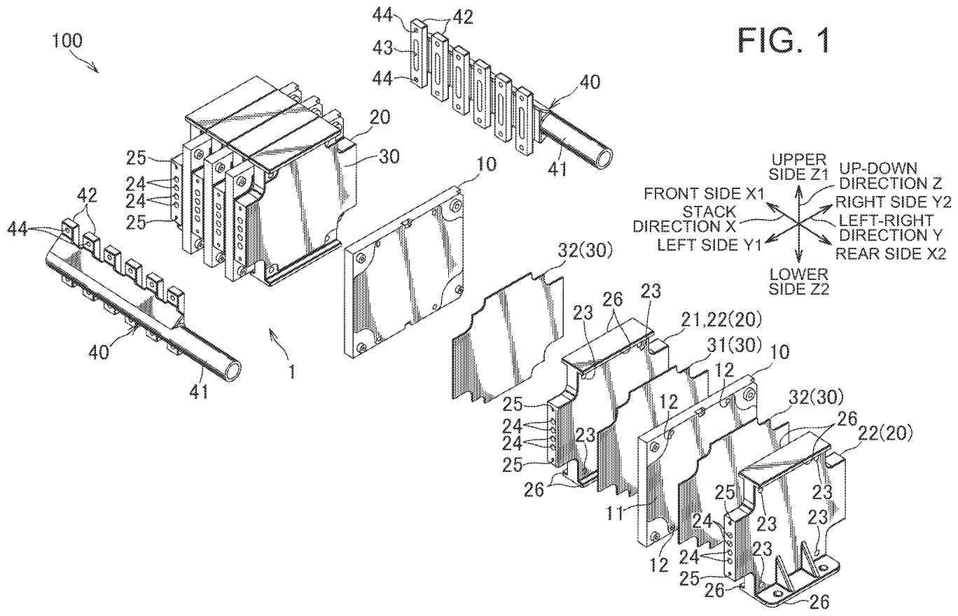

Hereinafter, an embodiment of a power supply device 100 including a heat dissipation structure 1 will be described based on FIG. 1 to FIG. 4C. According to the present embodiment, it is noted that an arrow X, an arrow Y, and an arrow Z in the drawings are directions orthogonal to each other. According to the present embodiment, a direction as a thickness direction of a heat generation body 10 described below and in which this heat generation body 10 is stacked is indicated by the arrow X and referred to as a “stack direction X”. Then, one side in the stack direction X is referred to as a “front side X1”, and the other side therein is referred to as a “rear side X2”. Also, a direction as a width direction of the heat generation body 10 is indicated by the arrow Y and referred to as a “left-right direction Y”. Then, one side in the left-right direction Y is referred to as a “left side Y1”, and the other side in the left-right direction is referred to as a “right side Y2”. Also, a height direction of the heat generation body 10 is indicated by the arrow Z and referred to as a “up-down direction Z”. Then, one side in the up-down direction Z is referred to as an “upper side Z1”, and the other side in the up-down direction is referred to as a “lower side Z2”.

The power supply device 100 is a device mounted on, for example, an electric vehicle including a hybrid vehicle, and is configured by stacking a plurality of converters or electronic components as a heat generation body 10. Examples of the converter include a DC/DC converter and the like that transforms the voltage of DC power, and examples of the electronic component include a semiconductor module and the like that contains a built-in semiconductor element. However, according to the present embodiment, the heat generation body 10 will be described as the DC/DC converter. The power supply device 100 includes the heat dissipation structure 1 as a structure for lowering the temperature since the heat generation body 10 becomes extremely hot when a large current flows therethrough. As shown in FIG. 1, the heat dissipation structure 1 includes the above-described heat generation body 10, a cooling plate 20 (cooling member), a heat dissipation sheet 30 (heat dissipation member), and a pipe 40. The heat generation body 10 as the DC/DC converter is formed into a rectangular plate shape, and includes a switching element, an input terminal, an output terminal, and the like which are not shown in figures. An arrangement area 11 for arranging the heat dissipation sheet 30 is formed on the surface of the heat generation body 10 facing the stack direction X. The external shape of the arrangement area 11 is formed to match the external shape of the heat dissipation sheet 30, and has a shape in which four corners of a rectangular shape are cut out in a R shape respectively. A pair of positioning holes 12 penetrating in the stack direction X are formed in each of an end portion at the upper side Z1 and an end portion at the lower side Z2 of the arrangement area 11, and the pair of positioning holes 12 are separated from each other at an interval therebetween in the left-right direction Y.

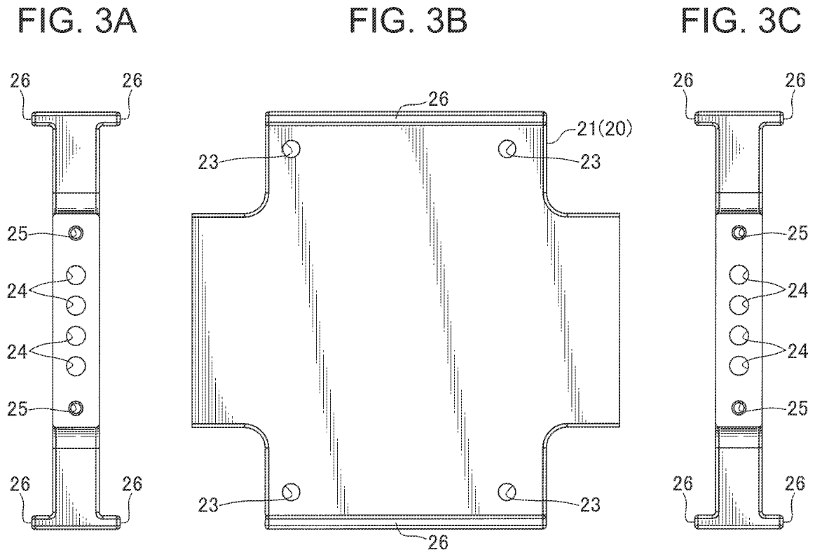

The cooling plate 20 includes a first cooling plate 21 arranged on the front side X1 (one side in the thickness direction) of the heat generation body 10, and a second cooling plate 22 arranged on the rear side X2 (the other side in the thickness direction) of the heat generation body 10. That is, the cooling plates 22 are arranged on one side and the other side of the heat generation body 10 in the stack direction X, respectively. It is noted that since the structures of the first cooling plate 21 and the second cooling plate 22 are the same with each other, the structure of the first cooling plate 21 will be described hereinafter and the description of the second cooling plate 22 will be omitted or simplified. The first cooling plate 21 is made of a thick plate member having a thickness in the stack direction X, and as shown in FIG. 3B, has a shape in which four corners of the rectangular shape are cut out in a R shape respectively. A pair of positioning holes 23 penetrating in the stack direction X are formed in each of an end portion at the upper side Z1 and an end portion at the lower side Z2 of the first cooling plate 21, and the pair of positioning holes 23 are separated from each other at an interval therebetween in the left-right direction Y. The positioning holes 23 are coaxial with the positioning holes 12 of the heat generation body 10 described above, respectively.

As shown in FIG. 3A and FIG. 3C, in a central portion of both side walls in the left-right direction Y of the first cooling plate 21, a plurality of refrigerant passages 24 penetrating in the left-right direction Y are formed side by side in the up-down direction Z. The refrigerant passages 24 is a flow passage in the first cooling plate 21 for passing through a refrigerant made of liquid or gas. According to the present embodiment, four refrigerant passages 24 are formed, however the number thereof is not particularly limited, and four or more refrigerant passages 24 or four or fewer refrigerant passages 24 may be formed. Fixing holes 25 being coaxial with holes 44, which will be described later, are formed in the end portion at the upper side Z1 and in the end portion at the lower side Z2 of the two side walls in the left-right direction Y of the first cooling plate 21 to open outwardly in the left-right direction Y. A female thread (not shown) is formed on an inner circumferential surface of the fixing hole 25. An upper edge portion and a lower edge portion of the first cooling plate 21 are formed with regulation protrusions 26 as regulation portions that protrude toward the front side X1 and the rear side X2, respectively.

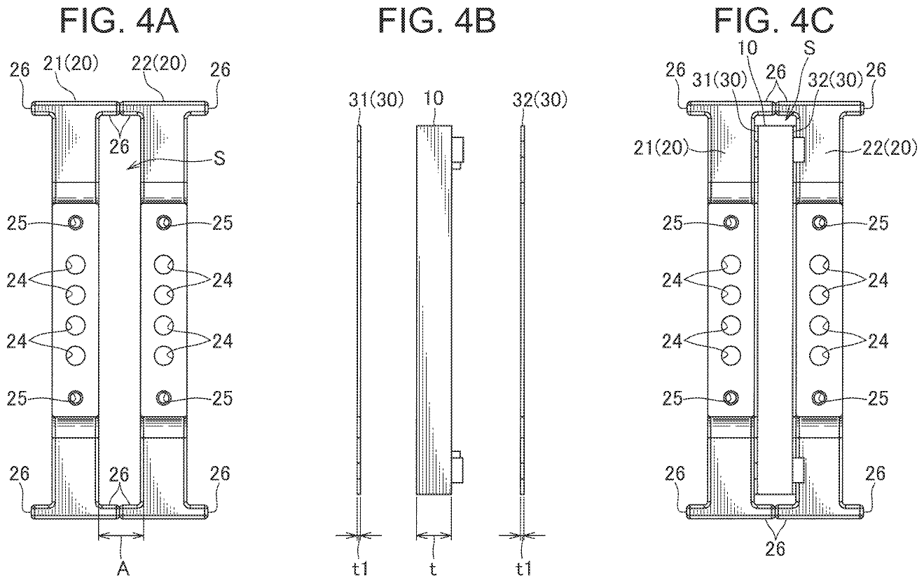

As shown in FIGS. 4A-4C, the regulation protrusion 26 are protrusions for partitioning a holding space S for holding the heat generation body 10 between the first cooling plate 21 (one cooling member) and the second cooling plate 22 (the other cooling member). The regulation protrusion 26 of the first cooling plate 21 and the regulation protrusion 26 of the second cooling plate protrude in a direction toward each other, and their protruding end portions are in contact with each other. As shown in FIG. 4A, a protrusion amount of the regulation protrusion 26 is set such that a dimension of the holding space S in the stack direction X becomes A when this regulation protrusion 26 is in contact with the regulation protrusion 26 as the contact target. As shown in FIG. 4B, it is preferable that A is set to satisfy the equation t<A< (t1+t+t1), where t is the dimension of the heat generation body 10 in the stack direction X, and t1 is the dimension of the heat dissipation sheet 30 in the stack direction X. With this setting, the heat generation body 10 is held between the cooling plate 20 and the heat dissipation sheet 30 with a constant pressing force in the stack direction X. Similar to this configuration, the regulation protrusion 26 as the regulation portion is provided between the cooling plates 20 that hold the heat generation body 10, and the regulation protrusion 26 defines a distance in the stack direction X from the first cooling plate 21 to the second cooling plate 22. According to the present embodiment, as described above, the regulation protrusions 26 are formed in the upper edge portion and the lower edge portion of the cooling plate 20, however, the present invention is not limited to this configuration. The regulation protrusions 26 may be formed in a left edge portion and a right edge portion of the cooling plate 20. That is, the regulation protrusions 26 are formed in both end portions of the cooling plate 20 in an intersecting direction intersecting the stack direction X.

The heat dissipation sheet 30 is configured of a first heat dissipation sheet 31 disposed on the front side X1 (one side in the thickness direction) of the heat generation body 10, and a second heat dissipation sheet 32 disposed on the rear side X2 (the other side in the thickness direction) of the heat generation body 10. That is, the heat dissipation sheet 30 is arranged on one side and the other side of the heat generation body 10 in the stack direction X, respectively. It is noted that since the structures of the first heat dissipation sheet 31 and the second heat dissipation sheet 32 are the same with each other, the structure of the first heat dissipation sheet 31 will be described hereinafter, and the description of the second heat dissipation sheet 32 will be omitted or simplified. The first heat dissipation sheet 31 is a member disposed between the heat generation body 10 and the cooling plate 20, and is formed into a sheet shape using an elastic material such as a resin. The first heat dissipation sheet 31 has a rectangular shape with four corners cut out in two steps in the up-down direction Z, respectively.

The pipe 40 is a structure for supplying a refrigerant to the refrigerant passages 24 of the cooling plate 20, and is arranged on both sides of the heat generation body 10, the cooling plate 20, and the heat dissipation sheet 30 in the left-right direction Y. The pipe 40 includes a pipe 41 and a branch portion 42. The pipe 41 is a pipe connected to a pump (not shown) and extends in the stack direction X. The branch portion 42 is a portion arranged in accordance with a certain position of the side wall of the cooling plate 20, and is formed in a rectangular parallelepiped shape extending in the up-down direction Z. A communication hole 43 that communicates with the pipe 41 and the refrigerant passage 24, and a hole 44 that communicates with the fixing hole 25 described above are formed in each of the branch portions 42. An opening edge portion of the communication hole 43 at an inner side in the left-right direction Y is formed in an oval shape that is elongated in the up-down direction Z so as to entirely cover the plurality of refrigerant passages 24. The hole 44 is formed to penetrate in the left-right direction Y. The pipe 40 with this configuration is attached to and detached from, in the left-right direction Y, the cooling plate 20 in the state of holding the heat generation body 10, when the positions of the communication holes 43 and the refrigerant passages 24 are aligned with each other. According to this configuration, in the state in which the pipe 40 is connected to the cooling plate 20, the pipe 40 communicates with the refrigerant passages 24 via the communication holes 43.

Next, the assembly of the power supply device 100 (heat dissipation structure 1) will be described. At first, as shown in FIG. 4B, the heat dissipation sheets 30 are disposed on both sides of the heat generation body 10 in the stack direction X. In this state, the cooling plates 20 are further disposed on both sides in the stack direction X, and as shown in FIG. 4C, the heat generation body 10 is held between the heat dissipation sheet 30 and the cooling plates 20. Then, a predetermined number of the heat generation bodies 10 held between the heat dissipation sheet 30 and the cooling plate 20 are stacked in the stack direction X. It is noted that during the stacking process, the cooling plates 20 may not be continuous in the stack direction X. Specifically, as shown in FIG. 1, it is possible to arrange the cooling plate 20 (second cooling plate 22), the heat dissipation sheet 30 (second heat dissipation sheet 32), the heat generation body 10, the heat dissipation sheet 30 (first heat dissipation sheet 31), the cooling plate 20 (first cooling plate 21, second cooling plate 22), the heat dissipation sheet 30 (second heat dissipation sheet 32), and so on side by side in this sequence from the rear side X2. That is, there is a case in which the cooling plates 20 other than the cooling plates 20 in both end portions in the stack direction X function as the first cooling plate 21 while also functioning as the second cooling plate 22.

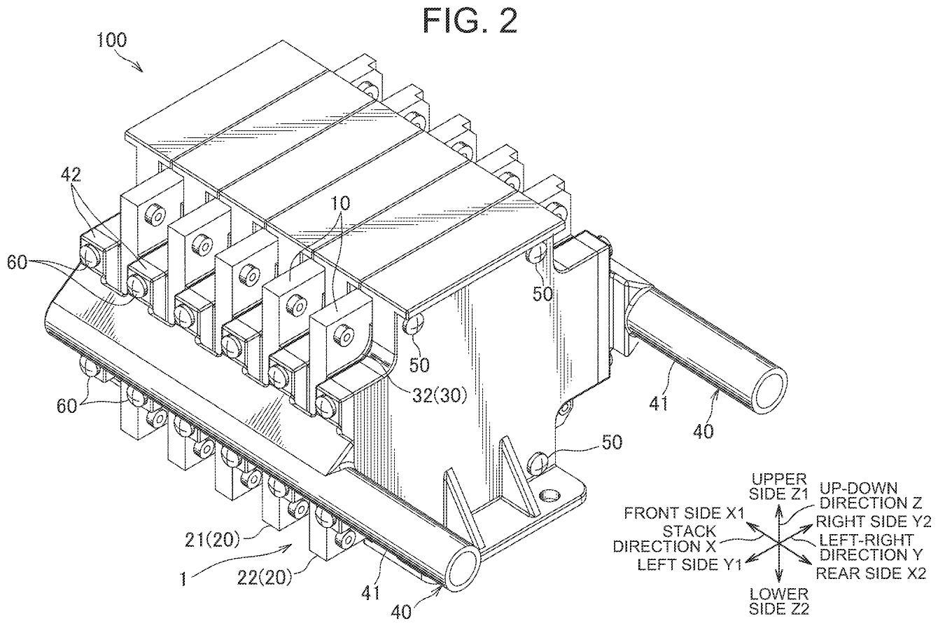

Next, long bolts 50 (positioning shafts, only shown in FIG. 2) are fastened to the positioning holes 12 of the heat generation bodies 10 and the positioning holes 23 of the cooling plates 20, and the plurality of heat generation bodies 10, cooling plates 20 and the heat dissipation sheets 30 are fixed together into one piece. Then, the pipes 40 are connected to both sides of the cooling plate 20 in the left-right direction Y. At the time of the connection, a screw 60 (only shown in FIG. 2) is inserted into the hole 44 with the communication hole 43 formed in the branch portion 42 communicating with the refrigerant passages 24, and the screw 60 is fastened to the fixing hole 25 of the cooling plate 20. It is noted that when connecting the pipes 40, it is preferable to perform a sealing process to seal the connection portion between the communication hole 43 of the branch portion 42 and the refrigerant passages 24. During the sealing process, in a case in which the refrigerant to be used is a liquid refrigerant, it is preferable to perform the sealing process strictly for improving the watertightness. On the other hand, in a case in which the refrigerant to be used is a gas refrigerant, it is unnecessary to require the sealing performance as much as that in the case of using the liquid refrigerant. Accordingly, the assembly of the power supply device 100 is completed.

According to the embodiment described above, by holding the heat generation body 10 in the stack direction X (thickness direction) by the cooling plate 20 (cooling member), the heat generated from the heat generation body 10 can be efficiently dissipated. Further, the distance in the stack direction X from the first cooling plate 21 (one cooling member) to the second cooling plate 22 (the other cooling member) can be defined by the regulation protrusion 26 (regulation portion). That is, the distance between the cooling plates 20 can be kept constant by the regulation protrusion 26. By keeping the distance between the cooling plates 20 constant, the pressing force when holding the heat generation body 10 can be kept constant, and it is possible to suppress the excessive pressing force and the repulsive force thereof from being applied to the heat generation body 10. Moreover, since the distance between the cooling plates 20 can be kept constant, the refrigerant passages 24 provided in the cooling plates 20 are arranged at the constant intervals in the stack direction X. That is, it is difficult for the positions of both end portions of the refrigerant passages 24 to be misaligned from the preset positions. Since the positions of both end portions of the refrigerant passages 24 are difficult to be misaligned in this way, it is possible to prevent any difficulty in connecting the pipes 40 to the cooling plate 20 due to dimensional errors in the heat generation body 10 and the like.

Also, the pipe 40 is provided to be able to communicate with the refrigerant passages 24 that penetrate the cooling plate 20 in the left-right direction Y (width direction), and the pipe 40 is attachable to and detachable from the cooling plate 20 in the left-right direction Y with the heat generation body 10 held therebetween. That is, the pipe 40 is attached and detached in the direction orthogonal to the direction in which the pressing force and the repulsive force thereof are applied when the cooling plate 20 presses the heat generation body 10. According to this configuration, it is difficult for the pressing force when the cooling plate 20 holds the heat generation body 10 and the repulsive force against the pressing force to be applied to the connection portion between the pipe 40 and the cooling plate 20. Since it is difficult for such a force to be applied to the connection portion, it is possible to prevent the connection of the pipe 40 from becoming difficult due to the above-mentioned pressing force or the repulsive force, and it is possible to facilitate the assembly of the power supply device 100, keeping the watertightness and the like. Furthermore, since it is not easy for the above-mentioned pressing force or the repulsive force to be applied to the connection portion between the pipe 40 and the cooling plate 20, it is difficult for the heat dissipation performance of the cooling plate 20 to fluctuate, and the reliability of the cooling plate 20 can be stably maintained. Also, since the pipe 40 can be attached to and detached from the cooling plate 20, there is no need to form any pipe integral with the cooling plate 20, and the structure of the cooling plate 20 can be simplified accordingly. Therefore, it is possible to obtain the heat dissipation structure 1 that suppresses the unintentional pressure from being applied to the heat dissipation target, improves the heat dissipation performance, and facilitates the assembly.

Also, according to the above-described configuration, the holding space S with the predetermined size is created between the cooling plates 20 by the regulation protrusions 26 being in contact with each other, and the heat generation body 10 can be disposed in this holding space S. With this arrangement, the distance between the cooling plates 20 when the heat generation body 10 is held between the cooling plates 20 can be kept constant regardless of the dimensional error in the stack direction X of the heat generation body 10. With this configuration, for example, it is unnecessary to adjust the positions of the plurality of branch portions 42 of the pipe 40 while connecting them to the cooling plate 20, and it is possible to connect the branch portions 42 to the cooling plate 20 in a state in which the branch portions 42 are grouped together in advance. Furthermore, for this connection, it only has to take the manufacturing errors of the holes 44 of the branch portion 42 and the fixing holes 25 of the cooling plate 20 into consideration, and it is unnecessary to take the manufacturing errors of the heat generation body 10 into consideration such that the design of the power supply device 100 becomes easier. Therefore, the manufacturing of the power supply device 100 can be facilitated.

Moreover, according to the above-described configuration, the heat generated from the heat generation body 10 can be efficiently transferred to the cooling plate 20 by the heat dissipation sheet 30 such that the heat dissipation performance of the heat dissipation structure 1 can be improved. Also, since the dimension t of the heat generation body 10 in the stack direction X is smaller than the dimension A of the holding space S in the stack direction X, it is possible to definitely hold the heat generation body 10 in the holding space S and absorb the dimensional errors of the heat generation body 10. Also, with this configuration, it is possible to make it difficult for the pressing force and the repulsive force thereof generated in the heat generation body 10 and the cooling plate 20 in the stack direction X to fluctuate as described above. Further, it is set that the dimension A is smaller than the (dimension t1+t+t1 of the heat dissipation sheet 30 in the stack direction X). With this setting, the heat dissipation sheet 30 is compressed in the stack direction X between the heat generation body 10 and the cooling plate 20 and comes into close contact therewith, and the cooling plate 20 holds the heat generation body 10 in this state. Therefore, the efficiency of the heat absorption by the heat dissipation sheet 30 and the cooling plate 20 can be improved, while the holding force of the heat generation body 10 by the cooling plate 20 can be improved while keeping the constant pressure.

Also, according to the above-described configuration, the holding space S can be partitioned by the regulation protrusions 26 provided on the upper side Z1 and the lower side Z2 of the cooling plate 20, respectively. With this configuration, it is possible to suppress one side of the cooling plate 20 on the upper side Z1 and the cooling plate 20 on the lower side Z2 from tilting in the stack direction X with respect to the other side. Therefore, it is possible to suppress the distortion of the holding space S in the stack direction X.

Further, according to the above-described configuration, it is possible to configure the power supply device 10 by using the heat dissipation structure that suppresses the unintentional pressing force from being applied to the heat generation body 10 (heat dissipation target), improving the heat dissipation performance and facilitates the assembly. In addition, in the case of this configuration, even if a plurality of heat generation bodies 10 are provided as being stacked in the stack direction X, the distance between the cooling plates 22 is kept constant as described above. Therefore, it is possible to stably maintain the state of suppressing the unintentional pressing force from being applied to the heat generation body 10, improving the heat dissipation performance, and facilitating the assembly.

Also, according to the above-described configuration, the positions of the heat generation body 10 and the cooling plate 20 stacked in the predetermined direction can be fixed by the bolts 50 (positioning shafts) inserted into the positioning hole 12 and the positioning hole 23. By fixing this position, it is possible to obtain the power supply device 100 in which the misaligning between the heat generation body 10 and the cooling plate 20 are unlikely to occur.

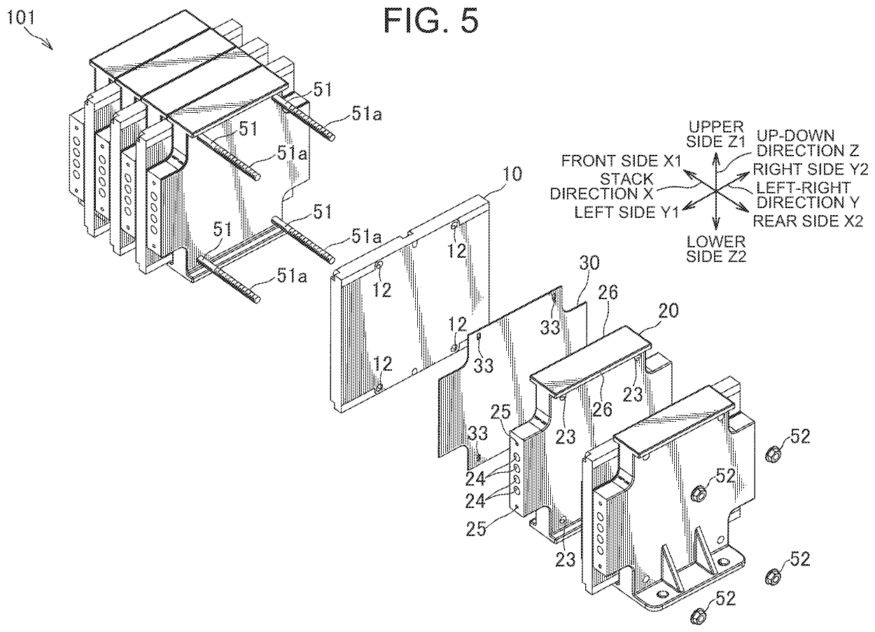

Although one embodiment of the present invention has been described above in detail with reference to the drawings, the specific structure is not limited to these embodiments, and even if there are design changes and the like made without departing from the gist of the present invention, they are also included in the scope of the present invention. FIG. 5 is an exploded perspective view showing a part of the power supply device 101 according to a first modification example. In the first modification example, a pair of positioning holes 33 penetrating in the stack direction X are respectively formed in each of the end portion at the upper side Z1 and the end portion at the lower side Z2 of the surface facing the stack direction X of the heat dissipation sheet 30 to be separated from each other in the left-right direction Y with the interval therebetween. The positioning holes 33 are coaxial with the positioning hole 12 of the heat generation body 10 and the positioning hole 23 of the cooling plate 20. A long positioning shaft 51 is inserted into these positioning holes 12, 23, 33.

The positioning shaft 51 is a member for suppressing the plurality of heat generation bodies 10, the cooling plates 20, and the heat dissipation sheets 30 that are stacked from misaligning in the left-right direction Y and the up-down direction Z. A male thread 51a is formed on the outer peripheral surface of an end portion of the positioning shaft 51 at the rear side X2, and a nut 52 is fastened to the male thread 51a. According to such a configuration, when assembling the power supply device 101, it is possible to perform the operations while preventing the positional misalignment of the heat generation body 10, the cooling plate 20, and the heat dissipation sheet 30. Also, since the pressing force applied to the heat generation body 10 in the stack direction X can be adjusted by the tightening amount of the nut 52, it is easy to easily and appropriately manage the pressing force applied to the heat generation body 10.

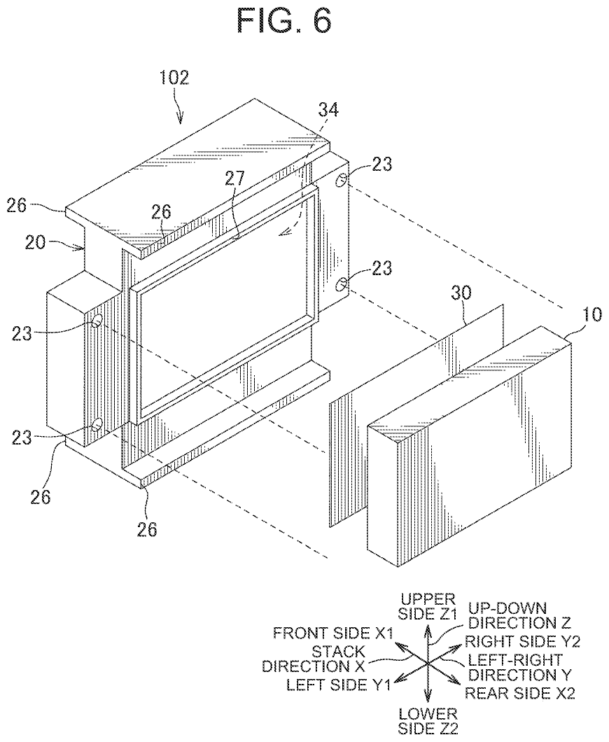

FIG. 6 is an exploded perspective view showing a part of the power supply device 102 according to a second modification example. In the second modification example, a pair of positioning holes 23 of the cooling plate 20 are formed at an interval in the up-down direction Z in an end portion at the left side Y1 and an end portion at the right side Y2 of a plate surface facing the stack direction X. Also, a positioning concave portion 27 being recessed in the stack direction X is formed on the plate surface of the cooling plate 20 facing in the stack direction X. The positioning recess portion 27 is a portion that fixes the position of the heat dissipation sheet 30 by accommodating the heat dissipation sheet 30, and is formed in a rectangular shape in correspondence to the external shape of the heat dissipation sheet 30. The heat dissipation sheet 30 is fitted into the positioning recess 27 in the stack direction X. In addition, at the time of this fitting, a heat dissipation grease 34 may be filled in the positioning recess 27 and disposed between the heat dissipation sheet 30 and the positioning recess 27, or the heat dissipation grease 34 may be used instead of the heat dissipation sheet 30 to be directly interposed between the heat generation body 10 and the cooling plate 20. According to such a configuration, the same functions and effects as those of the above-described embodiment and the first modification example can be achieved, while the variations of heat dissipation members that can be used in the heat dissipation structure 1 can be increased.

### REFERENCE SIGNS LIST

S holding space
X stack direction (thickness direction)
X1 front side (one side)
X2 rear side (the other side)
1 heat dissipation structure
10 heat generation body
20 cooling plate (cooling member)
26 regulation protrusion (regulation portion)

What is claimed is:

1. A heat dissipation structure, comprising:
a plate-shaped heat generation body;
cooling members disposed at one side and the other side in a thickness direction of the heat generation body respectively and configured to hold the heat generation body in the thickness direction;
a regulation portion provided between the cooling members holding the heat generation body and configured to regulate a distance from one of the cooling members to the other one of cooling members in the thickness direction; and
a pipe connected to the cooling members,
wherein a refrigerant passage penetrating in a width direction that is orthogonal to the thickness direction is provided in the cooling members, and
the pipe is provided to be able to communicate with the refrigerant passage, and is attachable to and detachable from, in the width direction, the cooling members in a state of holding the heat generation body.

2. The heat dissipation structure according to claim 1,
wherein the regulation portions are configured of regulation protrusions that are provided in each of the cooling members to protrude in a direction approaching each other in the thickness direction, and protruding end portions thereof come into contact with each other, and
in a state in which the regulation protrusions are in contact with each other, a holding space for holding the heat generation body is formed between one of the cooling members and the other of the cooling members.

3. The heat dissipation structure according to claim 2,
wherein an elastic sheet-shaped heat dissipation member is disposed between the heat generation body and the cooling member, and
when a dimension of the holding space in the thickness direction is referred to as A, a dimension of the heat generation body in the thickness direction is referred to as t, and a dimension of the heat dissipation member in the thickness direction is referred to as t1, a relationship as t<A< (t1+t+t1) is satisfied.

4. The heat dissipation structure according to claim 2,
wherein the regulation protrusions are provided in both end portions in an intersecting direction that intersects the thickness direction, respectively.

5. The heat dissipation structure according to claim 3,
wherein the regulation protrusions are provided in both end portions in an intersecting direction that intersects the thickness direction, respectively.

6. A power supply device, comprising the heat dissipation structure according to claim 1, wherein the heat generation body is configured of a converter or an electronic component, and the heat generation bodies are provided in a plural to be stacked in a predetermined direction.

7. A power supply device, comprising the heat dissipation structure according to claim 1,
wherein the heat generation body is configured of a converter or an electronic component, and the heat generation bodies are provided in a plural to be stacked in a predetermined direction,
positioning holes being coaxial with each other and penetrating in the predetermined direction are provided in the converter or the electronic component and the cooling members, and
positioning shafts configured to fix positions of the heat generation bodies and the cooling members are inserted into the positioning holes respectively.
